(19) United States
(12) Patent Application Publication
(10) Pub. No.: US 2026/0047330 A1
(43) Pub. Date: Feb. 12, 2026

(54) ADVANCED PATTERNING OLED STRUCTURE FOR ANODE PROTECTION

(71) Applicant: Applied Materials, Inc., Santa Clara, CA (US)

(72) Inventors: Ji Young CHOUNG, Hwaseong-si (KR); Chung-chia CHEN, Hsinchu City (TW); Sheng-Wen WANG, Tainan City (TW); Yu-Hsin LIN, Zhubei City (TW)

(21) Appl. No.: 19/271,378

(22) Filed: Jul. 16, 2025

Related U.S. Application Data
(60) Provisional application No. 63/682,270, filed on Aug. 12, 2024.

(51) Int. Cl. H10K 71/20; H10K 59/12; H10K 59/122

(52) U.S. Cl. CPC H10K 71/231; H10K 59/1201; H10K 59/122

(57) ABSTRACT

Embodiments described herein relate to a method of forming a sub-pixel. The method includes depositing an intermediate layer material over a substrate and an anode. The anode is disposed over the substrate. A separation structure material is disposed over the intermediate layer material. A portion of the separation structure material is removed to form separation structures. A first structure material and second structure material are deposited over the substrate. A portion of the first structure material and the second structure material are removed to form a first structure and a second structure. A portion of the intermediate layer material is removed to form an intermediate layer. An OLED material, a cathode, and an encapsulation layer are deposited over the intermediate layer. A resist is patterned in a first sub-pixel. A portion of the OLED material, the cathode, and the encapsulation layer exposed by the second resist are removed.

### CROSS-REFERENCE TO RELATED APPLICATIONS

This application claims priority to U.S. Provisional Ser. No. 63/682,270, filed Aug. 12, 2024, which is herein incorporated by reference in its entirety.

### BACKGROUND

### Field

Embodiments described herein generally relate to a display. More specifically, embodiments described herein relate to sub-pixel circuits and methods of forming sub-pixel circuits that may be utilized in a display such as an organic light-emitting diode (OLED) display.

### Description of the Related Art

Input devices including display devices may be used in a variety of electronic systems. An organic light-emitting diode (OLED) is a light-emitting diode (LED) in which the emissive electroluminescent layer is a film of an organic compound that emits light in response to an electric current. OLED devices are classified as bottom emission devices if light emitted passes through the transparent or semi-transparent bottom electrode and substrate on which the panel was manufactured. Top emission devices are classified based on whether or not the light emitted from the OLED device exits through the lid that is added following the fabrication of the device. OLEDs are used to create display devices in many electronics today. Today's electronics manufacturers are pushing these display devices to shrink in size while providing higher resolution than just a few years ago.

OLED pixel patterning is currently based on a process that restricts panel size, pixel resolution, and substrate size. Rather than utilizing a fine metal mask, photo lithography should be used to pattern pixels. Currently, OLED pixel patterning requires lifting off organic material after the patterning process. When lifted off, the organic material leaves behind a particle issue that disrupts OLED performance. Accordingly, what is needed in the art are sub-pixel circuits and methods of forming sub-pixel circuits to increase pixel-per-inch and provide improved OLED performance.

### SUMMARY

In one embodiment, a method of forming a device is disclosed. The method includes depositing an intermediate layer material over a substrate and an anode. The anode is disposed over the substrate. A separation structure material is disposed over the intermediate layer material. A portion of the separation structure material is removed to form separation structures. A first structure material and second structure material are deposited over the substrate. A portion of the first structure material and the second structure material are removed to form a first structure and a second structure. A portion of the intermediate layer material is removed to form an intermediate layer.

In another embodiment, a device is disclosed. A device includes a substrate, an anode disposed over the substrate, an intermediate layer disposed over the substrate and the anode, overhang structures disposed over the substrate and a plurality of sub-pixels. Each overhang structure includes a first structure and a second structure disposed over the first structure. The second structure has an overhang extension extending laterally past the first structure. Each sub-pixel includes an organic light-emitting diode (OLED) material extending under the overhang extension and a cathode disposed over the OLED material and extending under the overhang extension.

In yet another embodiment, a method of forming a device is disclosed. The method includes depositing an intermediate layer material over a substrate and an anode. The anode is disposed over the substrate. A separation structure material is disposed over the intermediate layer material. A portion of the separation structure material is removed to form separation structures. A first structure material and second structure material are deposited over the substrate. A portion of the first structure material and the second structure material are removed to form a first structure and a second structure. A portion of the intermediate layer material is removed to form an intermediate layer. An OLED material, a cathode, and an encapsulation layer are deposited over the intermediate layer. A resist is patterned in a first sub-pixel. A portion of the OLED material, the cathode, and the encapsulation layer exposed by the second resist are removed.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1A is a schematic, cross-sectional view of a sub-pixel circuit, according to embodiments.

FIG. 1B is a schematic, cross-sectional view of a portion of the sub-pixel circuit, according to embodiments.

FIG. 2 is a flow diagram of a method for forming a sub-pixel circuit, according to embodiments.

FIGS. 3A-3K are schematic, cross-sectional views of a substrate during a method of forming the sub-pixel circuit, according to embodiments.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein generally relate to a display. More specifically, embodiments described herein relate to sub-pixel circuits and methods of forming sub-pixel circuits that may be utilized in a display such as an organic light-emitting diode (OLED) display. In various embodiments, the sub-pixels employ advanced overhang structures to improve functionality of the display.

Each of the embodiments described herein of the sub-pixel circuit include a plurality of sub-pixels with each of the sub-pixels defined by adjacent overhang structures that are permanent to the sub-pixel circuit. While the Figures depict two sub-pixels with each sub-pixel defined by adjacent overhang structures, the sub-pixel circuit of the embodiments described herein include a plurality of sub-pixels, such as two or more subpixels. Each sub-pixel has OLED materials configured to emit a white, red, green, blue or other color light when energized, e.g., the OLED materials of a first sub-pixel emits a red light when energized, the OLED materials of a second sub-pixel emits a green light when energized, and the OLED materials of a third sub-pixel emits a blue light when energized.

The overhangs are permanent to the sub-pixel circuit and include at least a second structure disposed over a first structure. The adjacent overhang structures defining each sub-pixel of the sub-pixel circuit of the display provide for formation of the sub-pixel circuit using evaporation deposition and provide for the overhang structures to remain in place after the sub-pixel circuit is formed. Evaporation deposition is utilized for deposition of OLED materials (including a hole injection layer (HIL), a hole transport layer (HTL), an emissive layer (EML), and an electron transport layer (ETL)) and cathode. In some instances, an encapsulation layer may be disposed via evaporation deposition. In embodiments including one or more capping layers, the capping layers are disposed between the cathode and the encapsulation layer. The overhang structures and the evaporation angle set by the evaporation source define the deposition angles, i.e., the overhang structures provide for a shadowing effect during evaporation deposition with the evaporation angle set by the evaporation source. In order to deposit at a particular angle, the evaporation source is configured to emit the deposition material at a particular angle with regard to the overhang structure. The encapsulation layer of a respective subpixel is disposed over the cathode with the encapsulation layer extending under at least a portion of each of the adjacent overhang structures and along a sidewall of each of the adjacent overhang structures.

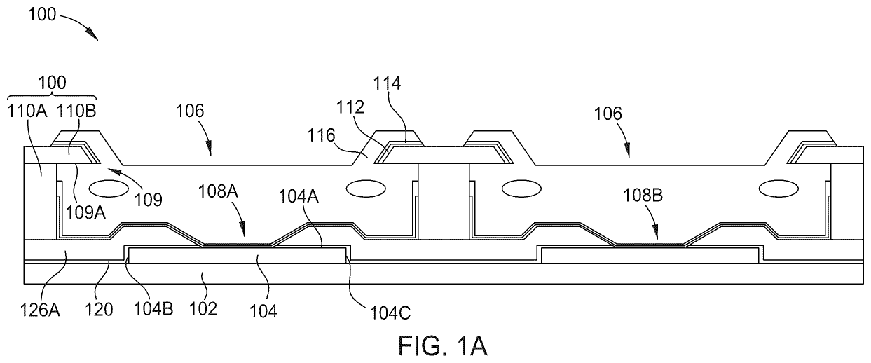

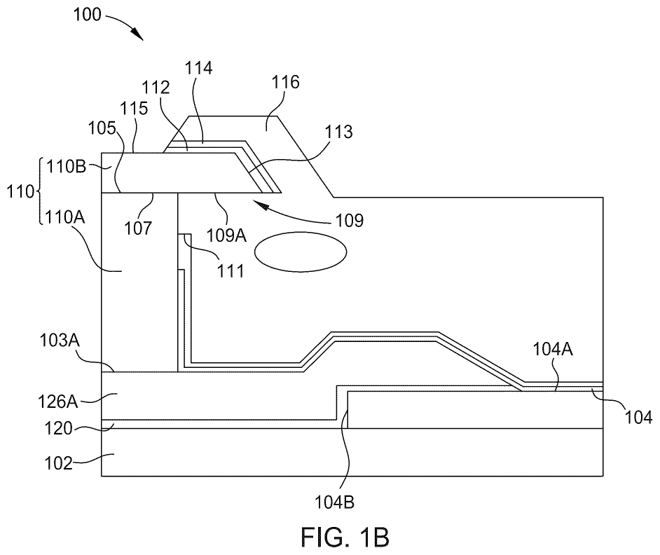

FIG. 1A is a schematic, cross-sectional view of a sub-pixel circuit 100. FIG. 1B is a portion of the schematic, cross-sectional view of a portion of the sub-pixel circuit 100. The sub-pixel circuit 100 includes a substrate 102. Metal-containing layers (e.g., anodes 104) may be patterned on the substrate 102 and are defined by adjacent separation structures 126A disposed on the substrate 102. In one embodiment, which may be combined with other embodiments, the anodes 104 are pre-patterned on the substrate 102. E.g., the substrate 102 is pre-patterned with anodes 104 of indium tin oxide (ITO). The anodes 104 are configured to operate as anodes of respective sub-pixels. In one embodiment, which may be combined with other embodiments, the anode 104 is a layer stack of a first transparent conductive oxide (TCO) layer, a second metal-containing layer disposed on the first TCO layer, and a third TCO layer disposed on the second metal-containing layer. The anodes 104 include, but are not limited to, chromium, titanium, gold, silver, copper, aluminum, ITO, a combination thereof, or other suitably conductive materials.

An intermediate layer 120 is disposed over the substrate 102 and the anode 104. The intermediate layer 120 is conformally deposited over a portion of an upper surface of the substrate 102, an upper surface 104A of the anode 104, and a first sidewall 104B and a second sidewall 104C of the anode 104. In some embodiments, the intermediate layer 120 is disposed on the substrate 102 and the anode 104. The separation structures 126A are disposed over the substrate 102 and disposed on the intermediate layer 120. The separation structures 126A include one of an organic material, an organic material with an inorganic coating disposed thereover, or an inorganic material. In some embodiments, which may be combined with other embodiments, the separation structures 126A may be an electrically insulative polymer. The organic material of the separation structures 126A includes, but is not limited to, polyimides. The inorganic material of the separation structures 126A includes, but is not limited to, silicon oxide (SiO₂), silicon nitride (Si₃N₄), silicon oxynitride (Si₂N₂O), magnesium fluoride (MgF₂), or combinations thereof. Adjacent separation structures 126A define respective sub-pixels and expose the anode 104 of the respective sub-pixel circuit 100.

The sub-pixel circuit 100 has a plurality of sub-pixels 106, including at least a first sub-pixel 108A and second sub-pixel 108B. While FIG. 1A depicts the first sub-pixel 108A and a second sub-pixel 108B, the sub-pixel circuit 100 of the embodiments described herein may include two or more sub-pixels, such as a third sub-pixel and a fourth sub-pixel. Each sub-pixel has OLED materials configured to emit a white, red, green, blue or other color light when energized, e.g., the OLED materials of the first sub-pixel 108A emits a red light when energized, the OLED materials of the second sub-pixel 108B emits a green light when energized, the OLED materials of a third sub-pixel emits a blue light when energized, and the OLED materials of a fourth sub-pixel emits another color light when energized.

Each sub-pixel 106 includes adjacent overhang structures 110, with adjacent sub-pixels sharing the adjacent overhang structures 110. The overhang structures 110 are permanent to the sub-pixel circuit 100. The overhang structures 110 further define each sub-pixel 106 of the sub-pixel circuit 100. Each overhang structure 110 includes adjacent overhangs 109. The adjacent overhangs 109 are defined by an overhang extension 109A of a second structure 110B extending laterally past an upper surface 105 of a first structure 110A. The second structure 110B is disposed over the first structure 110A. The second structure 110B may be disposed on the upper surface 105 of the first structure 110A. The first structure 110A is disposed over the substrate 102. In some embodiments, which may be combined with other embodiments, the first structure 110A is disposed over an upper surface 103A of the separation structures 126A.

In one embodiment, which may be combined with other embodiments, the overhang structures 110 include the second structure 110B of a non-conductive inorganic material and the first structure 110A of a conductive inorganic material. In another embodiment, the overhang structures 110 include the first structure 110A and the second structure 110B of a non-conductive inorganic material. In another embodiments, the first structure 110A and the second structure 110B are conductive inorganic materials. In another embodiment, the first structure 110A is a non-conductive inorganic material and the second structure 110B is a conductive inorganic material. The conductive materials include a copper (Cu), aluminum (Al), aluminum neodymium (AlNd), molybdenum (Mo), molybdenum tungsten (MoW), chromium (Cr), a transparent conductive oxide (e.g., indium-tin oxide (ITO) and indium-zinc oxide (IZO)), titanium (Ti), or combinations thereof. The non-conductive materials include amorphous silicon (a-Si), silicon nitride (Si₃N₄), silicon oxide (SiO₂), silicon oxynitride (Si₂N₂O), germanium (Ge), titanium (Ti), indium-tin oxide (ITO), germanium arsenide (GeAs III or IV), or combinations thereof. The overhang structures 110 are able to remain in place, i.e., are permanent.

The intermediate layer 120 is disposed over the substrate 102 and the anode 104. The intermediate layer 120 includes inorganic and non-conductive materials, such as aluminum oxide (Al₂O₃), silicon nitride (SiNₓ), silicon oxide (SiOₓ)or a combination thereof. The intermediate layer 120 has a thickness of about 0.1 nm to about 100 nm, such as about 1 nm to about 10 nm, such as about 3 nm to about 7 nm, such as about 5 nm. The intermediate layer 120 is deposited using atomic layer deposition (ALD), chemical vapor deposition (CVD), or physical vapor deposition (PVD). The intermediate layer 120 provides protection for the anode 104. In particular, the intermediate layer 120 provides protection to the anode 104 if seamlines are formed in the separation structures 126A. In addition, the intermediate layer 120 provides protection to the anode 104 during an etching operation to form the adjacent overhangs structures 110 and the separation structures 126A.

The adjacent overhangs 109 are defined by the overhang extension 109A. At least the bottom surface 107 of the second structure 110B is wider than the upper surface 105 of the first structure 110A to form the overhang extension 109A. The overhang extension 109A of the second structure 110B forms the overhang 109 and allows for the second structure 110B to shadow the first structure 110A. The shadowing of the overhang 109 provides for evaporation deposition of an OLED material 112 and a cathode 114. The OLED material 112 may include one or more of a HIL, a HTL, an EML, and an ETL. The OLED material 112 is disposed over and in contact with the anode 104. The OLED material 112 is disposed under adjacent overhangs 109 and may contact a sidewall 111 of the first structure 110A. In one embodiment, which may be combined with other embodiments, the OLED material 112 is different from the material of the first structure 110A and the second structure 110B. The cathode 114 is disposed over the OLED material 112 and extends under the adjacent overhangs 109. The cathode 114 may extend past an endpoint of the OLED material 112. The cathode 114 may contact the sidewall 111 of the first structure 110A. The overhang structures 110 and an evaporation angle set by an evaporation source define deposition angles, e.g., the overhang structures provide for a shadowing effect during evaporation deposition with the evaporation angle set by the evaporation source.

The cathode 114 includes a conductive material, such as a metal. E.g., the cathode 114 includes, but is not limited to, silver, magnesium, chromium, titanium, aluminum, ITO, or a combination thereof. In one embodiment, material of the cathode 114 is different from the material of the first structure 110A and the second structure 110B. In some embodiments, which may be combined with other embodiments, the OLED material 112 and the cathode 114 are disposed over a sidewall 113 of the second structure 110B of the overhang structures 110. In other embodiments, which may be combined with other embodiments, the OLED material 112 and the cathode 114 are disposed over an upper surface 115 of the second structure 110B of the overhang structures 110. In still other embodiments, which may be combined with other embodiments, the OLED material 112 and the cathode 114 end on the sidewall 111 of the first structure 110A, i.e., are not disposed over the sidewall 113 of the second structure 110B or the upper surface 115 of the second structure 110B.

Each sub-pixel 106 includes an encapsulation layer 116. The encapsulation layer 116 may be or may correspond to a local passivation layer. The encapsulation layer 116 of a respective sub-pixel is disposed over the cathode 114 and OLED material 112 with the encapsulation layer 116 extending under at least a portion of each of the overhangs 109 and along a sidewall 111 of each of the first structure 110A and the second structure 110B. The encapsulation layer 116 is disposed over the cathode 114 and extends at least to contact the cathode 114 over the sidewall 111 of the first structure 110A. In some embodiments, which may be combined with other embodiments, the encapsulation layer 116 extends to contact the sidewall 111 of the first structure 110A. In some embodiments, which may be combined with other embodiments, the encapsulation layer 116 extends to contact the second structure 110B at an underside surface of the overhang extension 109A, the sidewall 113 of the second structure 110B, and the upper surface 115 of the second structure 110B. In some embodiments, which may be combined with other embodiments, the encapsulation layer 116 extends to contact the second structure 110B at an underside surface of the overhang extension 109A and to be disposed over the OLED material 112 and the cathode 114 when the OLED material 112 and the cathode 114 are disposed over the sidewall 113 and upper surface 115 of the second structure 110B. In some embodiments, which may be combined with other embodiments, the encapsulation layer 116 ends at the sidewall 111 of the first structure 110A, i.e., is not disposed over the sidewall 113 of the second structure 110B, the upper surface 115 of the second structure 110B, or the underside surface of the overhang extension 109A of the overhang structures 110. The encapsulation layer 116 includes the non-conductive inorganic material, such as the silicon-containing material. The silicon-containing material may include Si₃N₄ containing materials.

In embodiments including one or more capping layers, which may be combined with other embodiments, the capping layers are disposed between the cathode 114 and the encapsulation layer 116. E.g., a first capping layer and a second capping layer are disposed between the cathode 114 and the encapsulation layer 116. Each of the embodiments described herein may include one or more capping layers disposed between the cathode 114 and the encapsulation layer 116. The first capping layer may include an organic material. The second capping layer may include an inorganic material, such as lithium fluoride. The first capping layer and the second capping layer may be deposited by evaporation deposition. In another embodiment, which may be combined with other embodiments, the sub-pixel circuit 100 further includes at least a global passivation layer disposed over the overhang structure 110 and the encapsulation layer 116. In yet another embodiment, the sub-pixel includes an intermediate passivation layer disposed over the overhang structures 110 of each of the sub-pixels 106, and disposed between the encapsulation layer 116 and the global passivation layer.

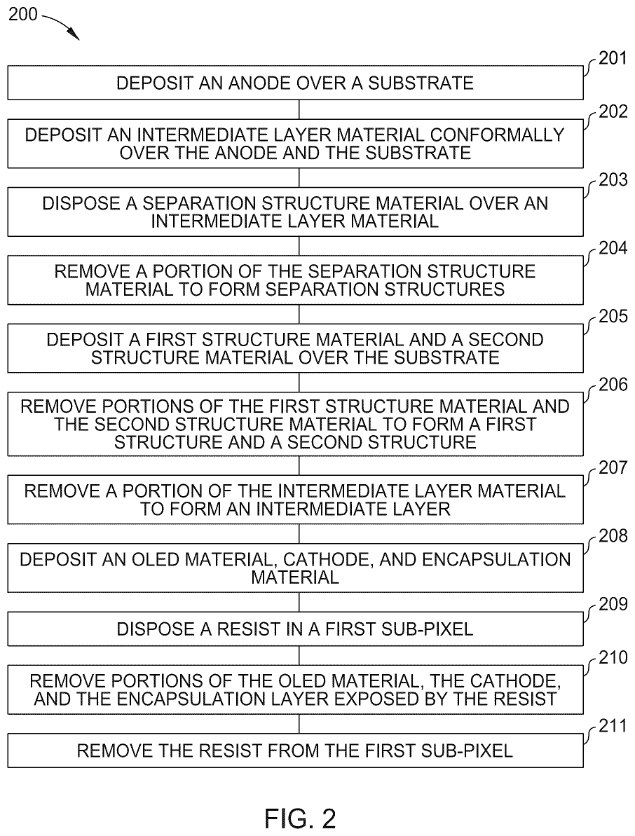

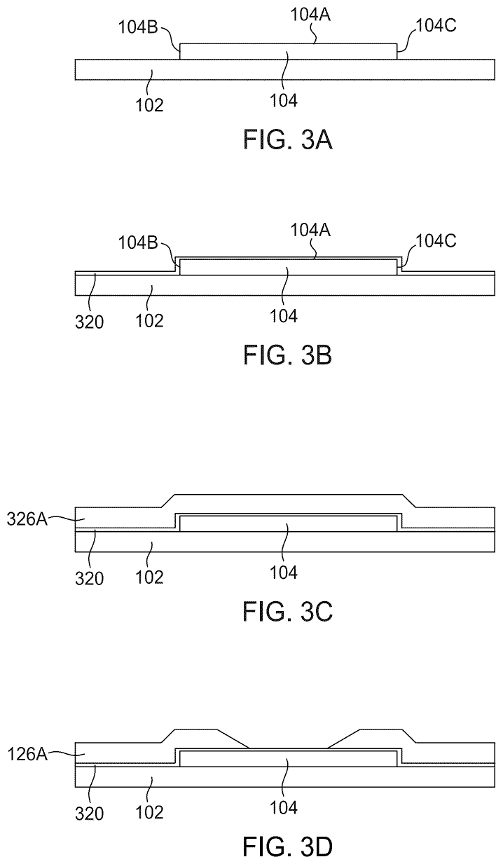

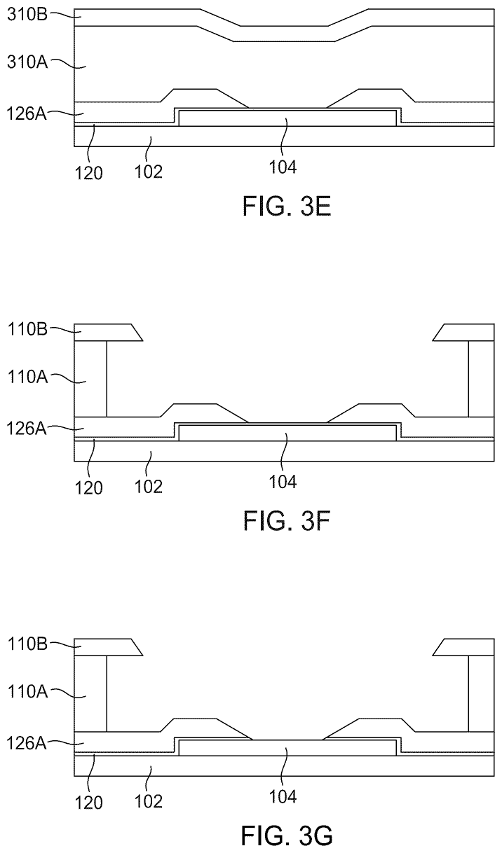

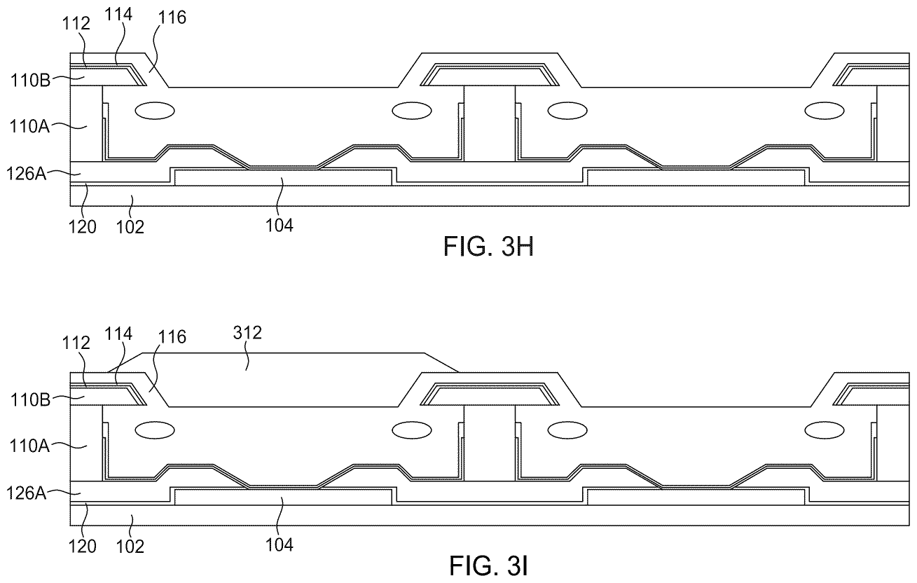

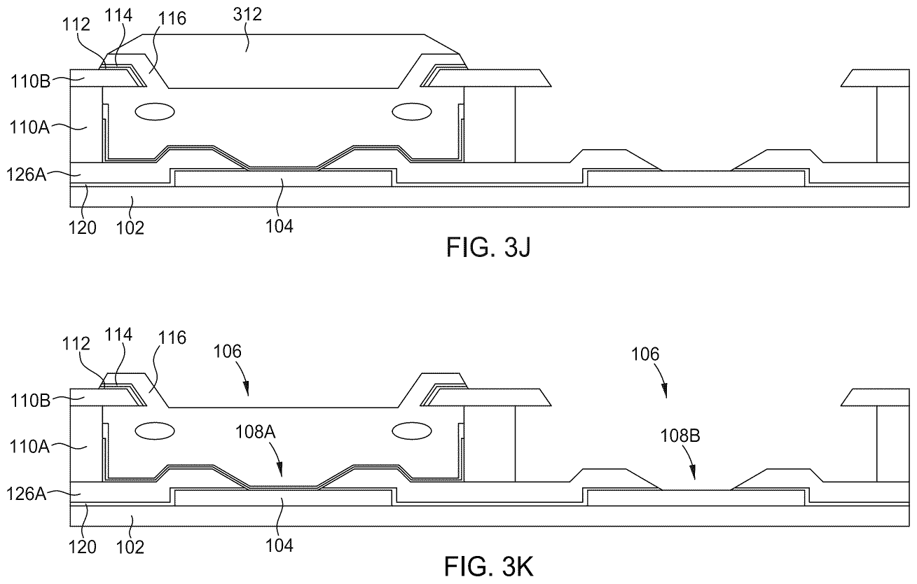

FIG. 2 is a flow diagram of a method 200 for forming a sub-pixel circuit 100 according to embodiment. FIG. 3A-3K are schematic, cross-sectional views of a substrate 102 during a method 200 for forming a sub-pixel circuit 100 according to embodiments described herein.

At operation 201, as shown in FIG. 3A, an anode 104 is deposited over the substrate 102. The anode 104 may be deposited on the substrate 102. The anode 104 may be deposited using metal-organic decomposition (MOD) or physical vapor deposition (PVD).

At operation 202, as shown in FIG. 3B, an intermediate layer material 320 is conformally deposited over the anode 104 and the substrate 102. The intermediate layer material 320 is deposited over the upper surface of the substrate 102, the upper surface 104A of the anode 104, and a first sidewall 104B and a second sidewall 104C of the anode 104. The intermediate layer material 320 includes inorganic and non-conductive materials, such as aluminum oxide (Al₂O₃), silicon nitride (SiNₓ), silicon oxide (SiOₓ) or a combination thereof. The intermediate layer material 320 has a thickness of about 0.1 nm to about 100 nm, such as about 1 nm to about 10 nm, such as about 3 nm to about 7 nm, such as about 5 nm. The intermediate layer material 320 is deposited using atomic layer deposition (ALD), chemical vapor deposition (CVD), or physical vapor deposition (PVD).

At operation 203, as shown in FIG. 3C, a separation structure material 326A is disposed over the intermediate layer material 320. The separation structure material 326A is deposited using chemical vapor deposition (CVD), ink jet printing (IJP), or slit/blade coating. The separation structure material 326A includes one of an organic material, an organic material with an inorganic coating disposed thereover, or an inorganic material. In some embodiments, which may be combined with other embodiments, the separation structure material 326A may be an electrically insulative polymer. The organic material of the separation structure material 326A includes, but is not limited to, polyimides. The inorganic material of the separation structure material 326A includes, but is not limited to, silicon oxide (SiO₂), silicon nitride (Si₃N₄), silicon oxynitride (Si₂N₂O), magnesium fluoride (MgF₂), or combinations thereof.

During deposition of the separation structure material 326A, potential seamlines may be formed in the separation structure material 326A near the anode 104. The intermediate layer material 320 protects the anode 104 against leakage damage via the seamlines.

At operation 204, as shown in FIG. 3D, a portion of the separation structure material 326A is removed to form separation structures 126A. The plurality of separation structures 126A separates the anode 104 from an adjacent anode 104. The separation structure material 326A is removed using a dry etch, such as a dry etch. The dry etch may be performed using SF₆ or CF₄ as an etchant gas. The anode 104 is protected from etching by the intermediate layer material 320 due to the etch selectivity between the separation structure material 326A and the intermediate layer material 320.

At operation 205, as shown in FIG. 3E, a first structure material 310A and a second structure material 310B are deposited over the substrate 102. The first structure material 310A is deposited over the anode 104, the intermediate layer material 320, and the separation structures 126A. The first structure material 310A includes a non-conductive inorganic material or a conductive material. A conductive material may be deposited using PVD. A non-conductive inorganic material may be deposited using CVD. The non-conductive materials include amorphous silicon (a-Si), silicon nitride (Si ₃N₄), silicon oxide (SiO₂), silicon oxynitride (Si₂N₂O), germanium (Ge), titanium (Ti), indium-tin oxide (ITO), germanium arsenide (GeAs III or IV), or combinations thereof. The conductive materials include a copper (Cu), aluminum (Al), aluminum neodymium (AlNd), molybdenum (Mo), molybdenum tungsten (MoW), chromium (Cr), a transparent conductive oxide (e.g., indium-tin oxide (ITO) and indium-zinc oxide (IZO)), titanium (Ti), or combinations thereof.

The second structure material 310B may be deposited using sputtering (e.g., PVD) if the second structure is a conductive material. A non-conductive material may be deposited using CVD. The second structure material 310B includes a conductive material or a non-conductive material. The conductive materials include a copper (Cu), aluminum (Al), aluminum neodymium (AlNd), molybdenum (Mo), molybdenum tungsten (MoW), chromium (Cr), a transparent conductive oxide (e.g., indium-tin oxide (ITO) and indium-zinc oxide (IZO)), titanium (Ti), or combinations thereof. The non-conductive materials include amorphous silicon (a-Si), silicon nitride (Si₃N₄), silicon oxide (SiO₂), silicon oxynitride (Si₂N₂O), germanium (Ge), titanium (Ti), indium-tin oxide (ITO), germanium arsenide (GeAs III or IV), or combinations thereof.

At operation 206, as shown in FIG. 3F, portions of the first structure material 310A and the second structure material 310B are removed to form the first structures 110A and second structures 110B. The second structure material 310B is removed using dry etching. The first structure material 310A is removed using wet or dry etching. The etch selectivity between the materials of the second structure material 310B corresponding to the second structure 110B, the first structure material 310A corresponding to the first structure 110A, and the etch processes to remove the exposed portions of the second structure material 310B and the first structure material 310A provide for the bottom surface 107 of the second structure 110B being wider than the upper surface 105 of the first structure 110A to form an overhang extension 109A of the adjacent overhangs 109. The shadowing of the adjacent overhangs 109 provide for evaporation deposition of the OLED material 112 and the cathode 114. The anode 104 is protected from etching by the intermediate layer material 320 due to the etch selectivity between the first structure material 310A and the intermediate layer material 320.

At operation 207, as shown in FIG. 3G, a portion of the intermediate layer material 320 is removed from anode 104 to form an intermediate layer 120. The intermediate layer material 320 may be removed using wet or dry etching. The wet etching may be performed using a tetramethylammonium hydroxide (TMAH).

At operation 208, as shown in FIG. 3H, an OLED material 112, a cathode 114, and an encapsulation layer 116 of the first sub-pixel 108A are deposited. The shadowing of the adjacent overhangs 109 provides for evaporation deposition of each of the OLED material 112 and the cathode 114.

At operation 209, as shown in FIG. 3I, a resist 312 is disposed in the first sub-pixel 108A. The resist 312 is a positive resist or a negative resist. The chemical composition of the resist 312 determine whether the resist 312 is a positive resist or a negative resist. The resist 312 is patterned to protect the first sub-pixel 108A from the subsequent etching processes. The patterning is one of a photolithography, digital lithography process, or laser ablation process.

At operation 210, as shown in FIG. 3J, portions of the OLED material 112, the cathode 114, and the encapsulation layer 116 exposed by the resist 312 are removed.

At operation 211, as shown in FIG. 3K, the resist 312 is removed from the first sub-pixel 108A. Operations 208 to 211 may be repeated until the desired number of sub-pixels are formed.

In summation, embodiments described herein of the sub-pixel circuit include a plurality of sub-pixels with each of the sub-pixels defined by adjacent overhang structures that are permanent to the sub-pixel circuit. The overhangs are permanent to the sub-pixel circuit and include at least a second structure disposed over a first structure. An intermediate layer is disposed over the substrate and the anode. The intermediate layer is conformally deposited over a portion of an upper surface of the substrate, an upper surface of the anode, and a first sidewall and a second sidewall of the anode. The intermediate layer provides protection to the anode if seamlines are formed in the separation structures. In addition, the intermediate layer provides protection to the anode during an etching operation to form the adjacent overhangs structures and the separation structures.

While the foregoing is directed to embodiments of the present disclosure, other and further embodiments of the disclosure may be devised without departing from the basic scope thereof, and the scope thereof is determined by the claims that follow.

What is claimed is:

1. A method of forming a device, comprising:
depositing an intermediate layer material over a substrate and an anode, wherein the anode is disposed over the substrate;
depositing a separation structure material over the intermediate layer material;
removing a portion of the separation structure material to form separation structures;
depositing a first structure material and second structure material over the substrate;
removing a portion of the first structure material and the second structure material to form a first structure and a second structure; and
removing a portion of the intermediate layer material to form an intermediate layer.

2. The method of claim 1, wherein the intermediate layer material comprises aluminum oxide, silicon nitride, or silicon oxide.

3. The method of claim 1, wherein removing the intermediate layer material is performed using a tetramethylammonium hydroxide etch.

4. The method of claim 1, wherein the intermediate layer material has a thickness of about 1 nm to about 10 nm.

5. The method of claim 1, wherein the first structure material comprises at least one of copper, aluminum, aluminum neodymium, molybdenum, indium-tin oxide, indium-zinc oxide, chromium, titanium, and molybdenum tungsten, or combinations thereof.

6. The method of claim 1, wherein the second structure material comprises an amorphous silicon, silicon nitride, silicon oxide, silicon oxynitride, germanium, titanium, indium-tin oxide, germanium arsenide, or combinations thereof.

7. The method of claim 1, wherein the separation structure material includes silicon oxide, silicon nitride, silicon oxynitride, or magnesium fluoride.

8. The method of claim 1, wherein removing the separation structure material is performed using a dry etch.

9. A device, comprising:
a substrate;
an anode disposed over the substrate;
an intermediate layer disposed over the substrate and the anode; and
overhang structures disposed over the substrate, each overhang structure comprising:
a first structure; and
a second structure disposed over the first structure, the second structure having an overhang extension extending laterally past the first structure;
a plurality of sub-pixels, each sub-pixel comprising:
an organic light-emitting diode (OLED) material extending under the overhang extension; and
a cathode disposed over the OLED material and extending under the overhang extension.

10. The device of claim 9, wherein the intermediate layer comprises aluminum oxide, silicon nitride, or silicon oxide.

11. The device of claim 9, wherein removing the intermediate layer is performed using a tetramethylammonium hydroxide etch.

12. The device of claim 9, wherein the intermediate layer has a thickness of about 1 nm to about 10 nm.

13. The device of claim 9, wherein the first structure comprises at least one of copper, aluminum, aluminum neodymium, molybdenum, indium-tin oxide, indium-zinc oxide, titanium, chromium, molybdenum tungsten, or combinations thereof.

14. The device of claim 9, wherein the second structure comprises an amorphous silicon, silicon nitride, silicon oxide, silicon oxynitride, germanium, titanium, indium-tin oxide, germanium arsenide, or combinations thereof.

15. The device of claim 9, further comprising an encapsulation layer disposed over the cathode.

16. The device of claim 15, wherein the encapsulation layer comprises a non-conductive inorganic material.

17. A method of forming a device, comprising:
depositing an intermediate layer material over a substrate and an anode, wherein the anode is disposed over the substrate;
depositing a separation structure material over the intermediate layer material;
removing a portion of the separation structure material to form separation structures;
depositing a first structure material and second structure material over the substrate;
removing a portion of the first structure material and the second structure material to form a first structure and a second structure; and
removing a portion of the intermediate layer material to form an intermediate layer;
depositing an organic light emitting diode (OLED) material, a cathode, and an encapsulation layer;
depositing and patterning a resist in a first sub-pixel;
removing a portion of the OLED material, the cathode, and the encapsulation layer exposed by the resist; and
removing the resist.

18. The method of claim 17, wherein the intermediate layer material has a thickness of about 1 nm to about 10 nm.

19. The method of claim 17, wherein the intermediate layer comprises aluminum oxide, silicon nitride, or silicon oxide.

20. The method of claim 17, wherein removing the intermediate layer is performed using a tetramethylammonium hydroxide etch.
